(19) United States
(12) Patent Application Publication
(10) Pub. No.: US 2018/0007780 A1
(43) Pub. Date: Jan. 4, 2018

(54) FLEXIBLE BOARD AND PRODUCTION METHOD FOR METAL WIRING BONDING STRUCTURE

(71) Applicant: NGK INSULATORS, LTD., Nagoya-City (JP)

(72) Inventors: Hiroshi TAKEBAYASHI, Handa-City (JP); Natsuki HIRATA, Handa-City (JP); Rishun KIN, Handa-City (JP)

(73) Assignee: NGK INSULATORS, LTD., Nagoya-City (JP)

(21) Appl. No.: 15/461,861

(22) Filed: Mar. 17, 2017

(30) Foreign Application Priority Data
Jun. 29, 2016 (JP) 2016-128767

(51) Int. Cl. H05K 1/02; H05K 1/11; H05K 3/36; H05K 3/40

(52) U.S. Cl. CPC H05K 1/028; H05K 3/4038; H05K 1/116; H05K 3/363

(57) ABSTRACT

A connection FPC 75 includes a plurality of metal wires 750 between a support layer 751 and a covering layer 752, and an exposed region including contacts 753 serving as end portions of the metal wires 750 is exposed from the covering layer 752. A bending-position guide 760 is provided on the surface of the support layer 751 opposite from the surface on which the metal wires 750 are provided. An edge 760a of the bending-position guide 760 serves as a bending line along which the connection FPC 75 is bent and is disposed in a covering-layer projection area E where the covering layer 752 is projected on the support layer 751. The connection FPC 75 is bent at portions of the metal wires 750 covered with the covering layer 752, that is, at reinforced portions.

### BACKGROUND OF THE INVENTION

### 1. Field of the Invention

The present invention relates to a flexible board and a production method for a metal wiring bonding structure.

### 2. Description of the Related Art

In a conventionally known structure for bonding a flexible board and a printed board, a contact part, such as a contact pattern, on the flexible board and a corresponding contact part on the printed board are electrically connected by soldering (for example, PTL 1). FIG. 9 illustrates an example of such a bonding structure. A coverlay film 912 is removed from a board end of a flexible board 910, where end portions of copper foil patterns arranged in parallel at a fixed pitch are exposed as a contact pattern 914. The contact pattern 914 is superposed on a contact pattern 924 provided on a printed board 920, and is electrically connected thereto by melting solder attached beforehand to a surface of at least one of the contact pattern 914 and the contact pattern 924.

### CITATION LIST

### Patent Literature

PTL 1: JP 5-90725 A

### SUMMARY OF THE INVENTION

However, in the bonding structure of FIG. 9, when the flexible board 910 needs to be bent near the contact pattern 914, it is sometimes bent at the contact pattern 914 exposed from the coverlay film 912. In this case, the contact pattern 914 may be broken because it is not reinforced by the coverlay film 912.

The present invention has been made to solve the above-described problem, and a main object of the invention is to prevent metal wires from being easily broken even when a flexible board is bent.

The present invention provides a flexible board including a plurality of metal wires between a first resin layer and a second resin layer, and an exposed region including contacts serving as end portions of the metal wires and exposed from the second resin layer,

wherein a bending-position guide is provided on a surface of the first resin layer opposite from a surface on which the metal wires are provided, and

an edge of the bending-position guide serves as a bending line along which the flexible board is bent and is disposed in a projection area where the second resin layer is projected on the first resin layer.

In this flexible board, the bending-position guide is provided on the surface of the first resin layer opposite from the surface on which the metal wires are provided. When the flexible board is bent, the edge of the bending-position guide serves as the bending line. The edge of the bending-position guide is disposed in the projection area where the second resin layer is projected on the first resin layer. For this reason, the flexible board is bent at portions of the metal wires covered with the second resin layer, that is, at reinforced portions. Therefore, even when the flexible board is bent, the metal wires are not easily broken.

In the flexible board of the present invention, the bending-position guide may be provided so as to cross a boundary between portions of the metal wires that are covered with the second resin layer and portions of the metal wires that are not covered with the second resin layer. Although this boundary tends to become the bending line when the flexible board is bent, since the bending-position guide crosses the boundary, it prevents the boundary from becoming the bending line.

In the flexible board of the present invention, a distance from the boundary between the portions of the metal wires that are covered with the second resin layer and the portions of the metal wires that are not covered with the second resin layer in the metal wires to the edge of the bending-position guide may be set to be equal to or more than a thickness of a portion of the flexible board in contact with the edge. In this case, when the flexible board is bent, the exposed portions of the metal wires are not greatly affected.

The flexible board of the present invention may include contact opposed lands formed of metal and respectively opposed to the contacts on the surface of the first resin layer opposite from the surface on which the metal wires are provided, and through holes penetrating the contact opposed lands, the first resin layer, and the contacts. The bending-position guide is preferably provided at such a position not to interfere with the contact opposed lands. In this case, a brazing and soldering material is more easily supplied to a bonding space than when the contact opposed lands and the through holes are not provided. As a result, it is possible to avoid the problem in that bonding is insufficient because the brazing and soldering material is not enough in the bonding space. Also, when the contact opposed lands are heated, heat thereof is transmitted to the bonding space via the first resin layer, and heat of the melted brazing and soldering material is also transmitted to the bonding space. For this reason, the bonding space is entirely heated to high temperature. As a result, the brazing and soldering material in the melted state supplied to the bonding space easily and uniformly wets and spreads inside the bonding space. In this way, the problem in that bonding is insufficient because the brazing and soldering material is not enough in the bonding space is avoided, and the brazing and soldering material in the melted state uniformly wets and spreads inside the bonding space. Hence, the contacts of the flexible board are firmly bonded to contacts of a different wiring board.

The present invention provides a production method for a metal wiring bonding structure, including:

(a) a step of brazing and soldering the contacts of the above-described flexible board to contacts of a different wiring board; and

(b) a step of bending the flexible board along a bending line formed by the edge of the bending-position guide.

In this production method for the metal wiring bonding structure, after the contacts of the flexible board are brazed and soldered to the contacts of the different wiring board, the flexible board is bent along the bending line formed by the edge of the bending-position guide. The edge of the bending-positioning guide is disposed in the projection area where the second resin layer is projected on the first resin layer. For this reason, the flexible board is bent at portions of the metal wires covered with the second resin layer, that is, reinforced portions. Therefore, even when the flexible board is bent, the metal wires are not easily broken.

In the production method for the metal wiring bonding structure of the present invention, in the step (b), the flexible board may be bent along the bending line formed by the edge of the bending-position guide while the bending-position guide is held from above by a pressing member from a side of the flexible board close to the contacts. This allows the edge to be more reliably used as the bending line.

In the production method for the metal wiring bonding structure of the present invention, in the step (a), the above-described flexible board including the contact opposed lands and the through holes may be used, and the contacts of the flexible board may be brazed and soldered by supplying a brazing and soldering material melted at the contact opposed lands of the flexible board between the contacts of the flexible board and the contacts of the different wiring board through the through holes and then hardening the brazing and soldering material. In this case, the brazing and soldering material melted at the contact opposed lands can be smoothly supplied to the bonding space between the contacts of the flexible board and the contacts of the different wiring board through the through holes. For this reason, the bonding space is easily filled with the brazing and soldering material without any gap therebetweon, and this increases bonding strength.

### BRIEF DESCRIPTION OF THE DRAWINGS

FIG. 1 is a cross-sectional view illustrating a schematic configuration of a plasma treatment apparatus 10.

FIG. 2 is a perspective view illustrating an internal structure of a sheet heater 30.

FIG. 3 is a plan view of a metal wiring bonding structure 100 when viewed from a lower surface 30b of the shoot heater 30.

FIG. 4 is a cross-sectional view taken along line A-A of FIG. 3.

FIGS. 5A and 5B include explanatory views illustrating a procedure for bending a connection FPC 75.

FIGS. 6A to 6D include explanatory views illustrating a production process for a connection FPC 75.

FIG. 7 is a plan view of a metal wiring bonding structure 200 when viewed from a lower surface 30b of the sheet heater 30.

FIG. 8 is a cross-sectional view taken along line B-B of FIG. 7.

FIG. 9 is a perspective view of a conventional metal wiring bonding structure.

### DETAILED DESCRIPTION OF THE INVENTION

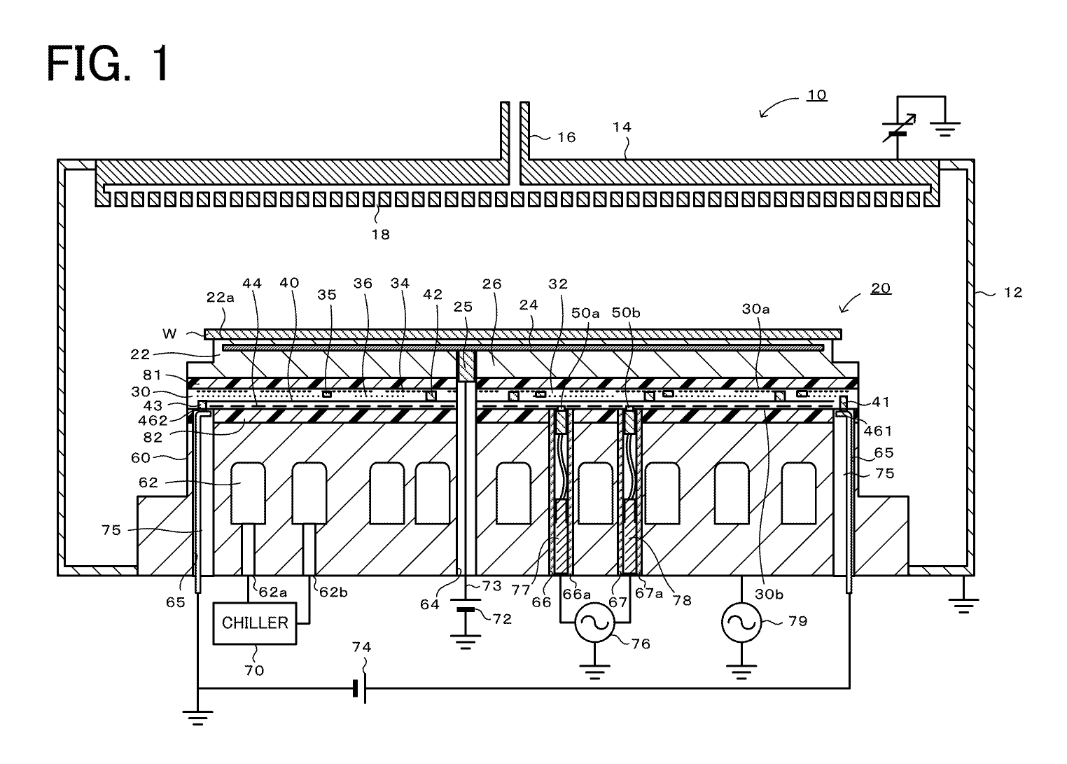

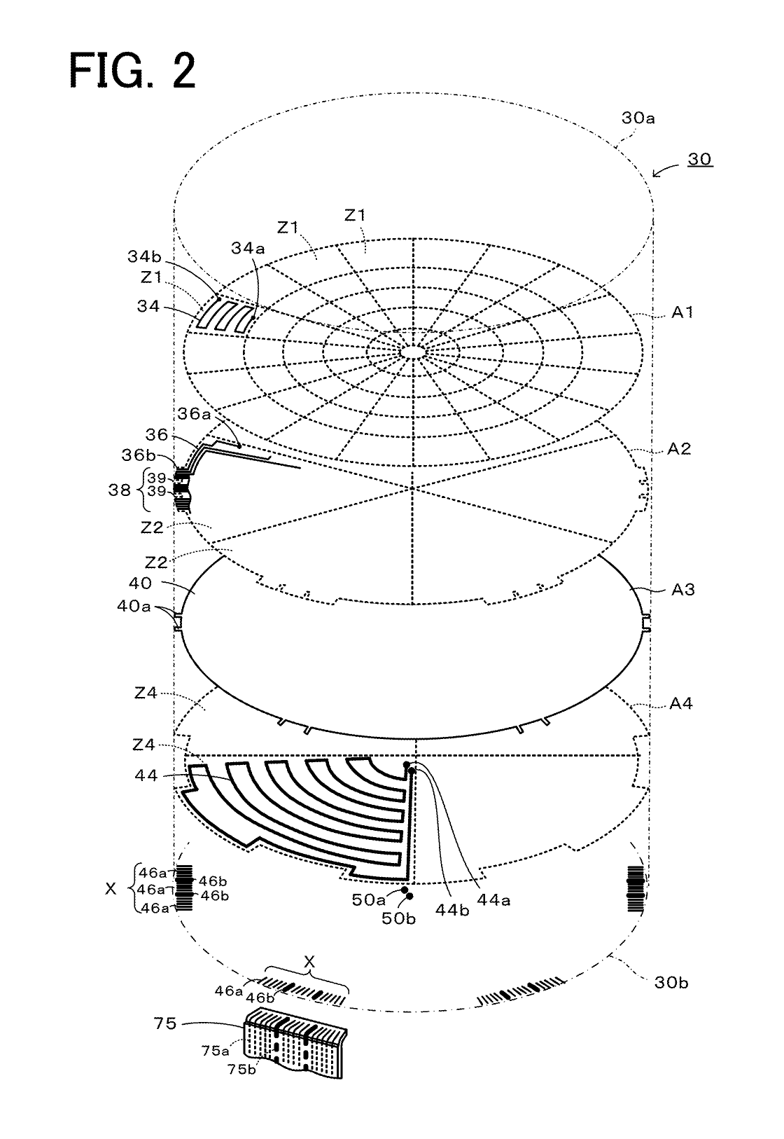

A preferred embodiment of the present invention will be described below with reference to the drawings. FIG. 1 is a cross-sectional view illustrating a schematic configuration of a plasma treatment apparatus 10, and FIG. 2 is a perspective view illustrating an internal structure of a sheet heater 30.

As illustrated in FIG. 1, the plasma treatment apparatus 10 serving as a semiconductor manufacturing apparatus includes a vacuum chamber 12, a shower head 14, and an electrostatic chuck heater 20. The vacuum chamber 12 is a box-shaped container formed of, for example, an aluminum alloy. The shower head 14 is provided in a ceiling surface of the vacuum chamber 12. The shower head 14 releases process gas supplied from a gas introduction pipe 16 into the vacuum chamber 12 through multiple gas injection ports 18. Also, the shower head 14 functions as a cathode plate for plasma generation. The electrostatic chuck heater 20 is a device that attracts and holds a wafer W on a wafer mounting surface 22a. Hereinafter, the electrostatic chuck heater 20 will be described in detail.

The electrostatic chuck heater 20 includes an electrostatic chuck 22, a sheet heater 30, and a support pedestal 60. A lower surface of the electrostatic chuck 22 and an upper surface 30a of the sheet heater 30 are bonded together with a first bonding shoot 81 interposed therebetween. An upper surface of the support pedestal 60 and a lower surface 30b of the sheet heater 30 are bonded together with a second bonding sheet 82 interposed therebetween. Examples of the bonding sheets 81 and 82 include a sheet in which an acrylic resin layer is provided on each surface of a core material formed of polypropylene, a sheet in which a silicone resin layer is provided on each surface of a core material formed of polyimide, and a sheet formed of epoxy resin alone.

The electrostatic chuck 22 is a disc-shaped member in which an electrostatic electrode 24 is embedded in a ceramic sintered body 26. Examples of the ceramic sintered body 26 include an aluminum nitride sintered body and an alumina sintered body. An upper surface of the electrostatic chuck 22 serves as a wafer mounting surface 22a on which a wafer W is mounted. The thickness of the ceramic sintered body 26 is preferably 0.5 to 4 mm, although not particularly limited.

The sheet heater 30 is a disc-shaped member in which correction heater electrodes 34, jumper lines 36, a around electrode 40, and reference heater electrodes 44 are built in a heat-resistant resin sheet 32. Examples of the material of the resin sheet 32 include polyimide resin and a liquid crystal polymer. The sheet heater 30 includes a first electrode region A1 to a fourth electrode region A4 provided parallel to the upper surface 30a of the sheet heater 30 and having different heights (see FIG. 2).

A first electrode region A1 is divided into multiple zones Z1 (for example, 100 zones or 300 zones). In each of the zones Z1, a correction heater electrode 34 is routed all over the zone Z1 from one end 34a to the other end 34b in the shape of a single brush stroke. In FIG. 2, imaginary lines are drawn by dotted lines in the first electrode region A1, and portions surrounded by the imaginary lines are referred to as zones Z1. While the collection heater electrode 34 is shown only in one zone Z1 in FIG. 2 for convenience, similar correction heater electrodes 34 are provided in the other zones Z1. The outer shape of the sheet heater 30 is shown by one-dot chain lines.

In a second electrode region A2, jumper lines 36 are provided to respectively supply power to the plural correction heater electrodes 34. For this reason, the number of jumper lines 36 is equal to the number of correction heater electrodes 34. The second electrode region A2 is divided into a number of zones Z2 smaller than the number of zones Z1 (for example, 6 zones or 8 zones). In FIG. 2, imaginary lines are drawn by dotted lines in the second electrode region A2, and portions surrounded by the imaginary lines are referred to as zones Z2. While a jumper line 36 (a part) is shown only in one zone Z2 for convenience in FIG. 2, similar jumper lines 36 are provided in the other zones Z2. In the description of the embodiment, it is assumed that, when one zone Z2 is projected onto the first electrode region A1, a plurality of correction heater electrodes 34 included in the projection area belong to the same group. One end 34a of each of the correction heater electrodes 34 belonging to one group is connected to one end 36a of the jumper line 36 in the zone Z2 corresponding to the group through a via 35 penetrating a portion between the first electrode region A1 and the second electrode region A2 in the up-down direction (see FIG. 1). The other end 36b of the jumper line 36 is extended out to an outer peripheral region 38 provided in the zone Z2. As a result, the other ends 36b of the jumper lines 36 connected to the correction heater electrodes 34 belonging to the same group are collectively disposed in one outer peripheral region 38. In regions X where outer peripheral regions 38 are projected onto the lower surface 30b of the sheet heater 30, jumper lands 46a connected to the other ends 36b of the jumper lines 36 through vias 41 (see FIG. 1) are arranged side by side. In other words, the plural jumper lands 46a are arranged in the same region X and exposed outside so that two or more jumper lands 46a form a group. The specific resistance of the correction heater electrodes 34 is preferably higher than or equal to the specific resistance of the jumper lines 36.

In a third electrode region A3, a ground electrode 40 common to the plural correction heater electrodes 34 is provided. The correction heater electrodes 34 are connected to the ground electrode 40 through vias 42 extending from the first electrode region A1 to the third electrode region A3 through the second electrode region A2 (see FIG. 1). The ground electrode 40 has projections 40a projecting outward from the outer periphery. These projections 40a are provided at positions opposed to cutouts 39 in the corresponding outer peripheral regions 38. The projections 40a are connected to ground lands 46b provided on the lower surface 30b of the sheet heater 30 through vias 43 (see FIG. 1). The ground lands 46b are provided together with the jumper lands 46a in the region X of the lower surface 30b of the sheet heater 30.

A fourth electrode region A4 is divided into a number of zones Z4 smaller than the total number of correction heater electrodes 34 provided in the first electrode region A1 (for example, 4 zones or 6 zones). In each of the zones Z4, a reference heater electrode 44 of an output higher than that of the correction heater electrodes 34 is routed over the entire zone Z4 from one end 44a to the other end 44b in the shape of a single brush stroke. In FIG. 2, imaginary lines are drawn by dotted lines in the fourth electrode region A4, and portions surrounded by the imaginary lines are referred to as zones Z4. While the reference heater electrode 44 is shown only in one zone Z4 for convenience in FIG. 2, similar reference heater electrodes 44 are also provided in the other zones Z4. Both ends 44a and 44b of each of the reference heater electrodes 44 are connected to a pair of reference lands 50a and 50b provided on the lower surface 30b of the sheet heater 30 through unillustrated vias extending from the fourth electrode region A4 to the lower surface 30b of the sheet heater 30.

As illustrated in FIG. 1, the support pedestal 60 is a disc-shaped member formed of metal such as A1 or an A1 alloy, and a refrigerant flow passage 62 is provided therein. A chiller 70 for adjusting the temperature of the refrigerant is connected to an entrance 62a and an exit 62b of the refrigerant flow passage 62. When the refrigerant is supplied from the chiller 70 to the entrance 62a of the refrigerant flow passage 62, it passes through the refrigerant flow passage 62 extending all over the support pedestal 60, is returned from the exit 62b of the refrigerant flow passage 62 to the chiller 70, is cooled to a setting temperature inside the chiller 70, and is then supplied to the entrance 62a of the refrigerant flow passage 62 again. The support pedestal 60 has a plurality of types of through holes 64 to 67 penetrating the support pedestal 60 in the up-down direction. The through hole 64 is a hole through which a power feed terminal 25 of the electrostatic electrode 24 is exposed outside. The through holes 65 are holes through which land groups (jumper lands 46a and ground lands 46b, see FIG. 2) provided in the regions X on the lower surface 30b of the sheet heater 30 are exposed outside. The through holes 66 and 67 allow the reference lands 50a and 50b of the reference heater electrodes 44 to be exposed outside therethrough. Electric insulating cylinders 66a and 67a are inserted in the through holes 66 and 67, respectively. The support pedestal 60 further includes, for example, unillustrated through holes in which lift pins for lifting up the wafer W are moved up and down.

The plasma treatment apparatus 10 further includes an electrostatic-chuck power supply 72, a correction-heater power supply 74, a reference-heater power supply 76, and an RF power supply 79. The electrostatic-chuck power supply 72 is a direct-current power supply, and is connected to the power feed terminal 25 of the electrostatic electrode 24 with a power feeding rod 73 inserted in the through hole 64 being interposed therebetween. The correction-heater power supply 74 is a direct-current power supply, and is connected to the jumper lands 46a and the ground lands 46b in the correction heater electrodes 34 with connection flexible printed circuit boards (connection FPC) 75 serving as metal-wiring assembly inserted in the through holes 65 being interposed therebetween. Specifically, since the jumper lands 46a and the ground lands 46b belonging to the same group illustrated in FIG. 2 are arranged in the same region X, they are connected through one connection FPC 75. The connection FPC 75 is a cable in which metal wires 75a and 75b coveted with resin coating are bundled in the form of band, and in an end portion opposed to the region X, the metal wires 75a and 75b are exposed. The metal wires 75a are lead wires that connect the jumper lands 46a to a positive electrode of the correction-heater power supply 74, and the metal wires 75b are lead wires that connect the ground lands 46b to a negative electrode of the correction-heater power supply 74. The reference-heater power supply 76 is an alternating-current power supply, is connected to one reference land 50a of each of the reference heater electrodes 44 through a cable terminal 77 inserted in the through hole 66, and is connected to the other reference land 50b of the reference heater electrode 44 through a cable terminal 78 inserted in the through hole 67. The RF power supply 79 is a power supply for plasma generation, and is connected to supply high-frequency power to the support pedestal 60 functioning as an anode plate. The shower head 14 functioning as the cathode plate is grounded through a variable resistor.

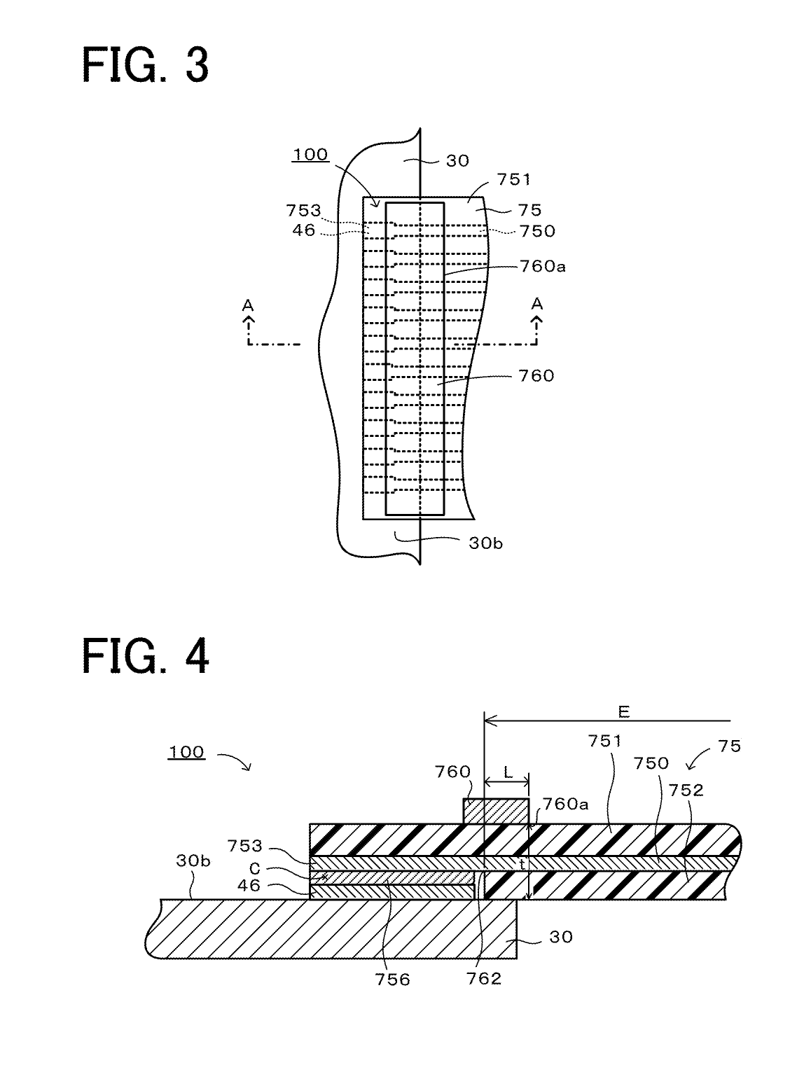

Here, a metal wiring bonding structure 100 for the sheet heater 30 and the connection FPC 75 will be described with reference to FIGS. 3 and 4. FIG. 3 is a plan view of the metal wiring bonding structure 100, when viewed from the lower surface 30b of the sheet heater 30, and FIG. 4 is a cross-sectional view taken along line A-A of FIG. 3. For convenience, the jumper lands 46a and the ground lands 46b are not distinguished, but are simply referred to as heater lands 46, and the metal wires 75a and 75b are also not distinguished, but are referred to as metal wires 750. The sheet heater 30 includes a plurality of heater lands 46 (46a, 46b) exposed in the regions X on the lower surface 30b (see FIG. 2). The connection FPC 75 is a flat wire material formed by covering a plurality of metal wires 750 with resin. Specifically, the connection FPC 75 has a plurality of metal wires 750 between a support layer 751 formed of resin and a covering layer 752 formed of resin. An exposed region including contacts 753 serving as end portions of the metal wires 750 is exposed from the covering layer 752. The connection FPC 75 is provided with a bending-position guide 760 on a surface of the support layer 751 opposite from a surface on which the metal wires 750 are provided. An edge 760a of the bending-position guide 760 is disposed in a covering-layer projection area E where the covering layer 752 is projected on the support layer 751, and serves as a bending line along which the connection FPC 75 is bent. The bending-position guide 760 is provided so as to cross a boundary 762 between portions that are covered with the covering layer 752 and portions that are not covered with the covering layer 752 in the metal wires 750. A distance L from the boundary 762 to the edge 760a of the bending-position guide 760 is set to be equal to or more than a thickness t (for example, 0.2 to 0.3 IMO of a portion of the connection FPC 75 in contact with the edge 760a. A solder bonding member 756 is filled in a bonding space C between the contacts 753 and the heater lands 46. To solder the contacts 753 and the heater lands 46, first, preliminary solder is applied onto upper surfaces of the heater lands 46. As the preliminary solder, for example, solder cream can be used. Next, the contacts 753 are placed in contact with the preliminary solder in a state in which they are opposed to the heater lands 46. The preliminary solder is melted by applying heat from hot air of a spot heater, and is then hardened by cooling. The contacts 753 and the heater lands 46 are thereby bonded with the solder bonding member 756 interposed therebetween. The support layer 751 and the covering layer 752 respectively correspond to the first resin layer and the second resin layer of the present invention.

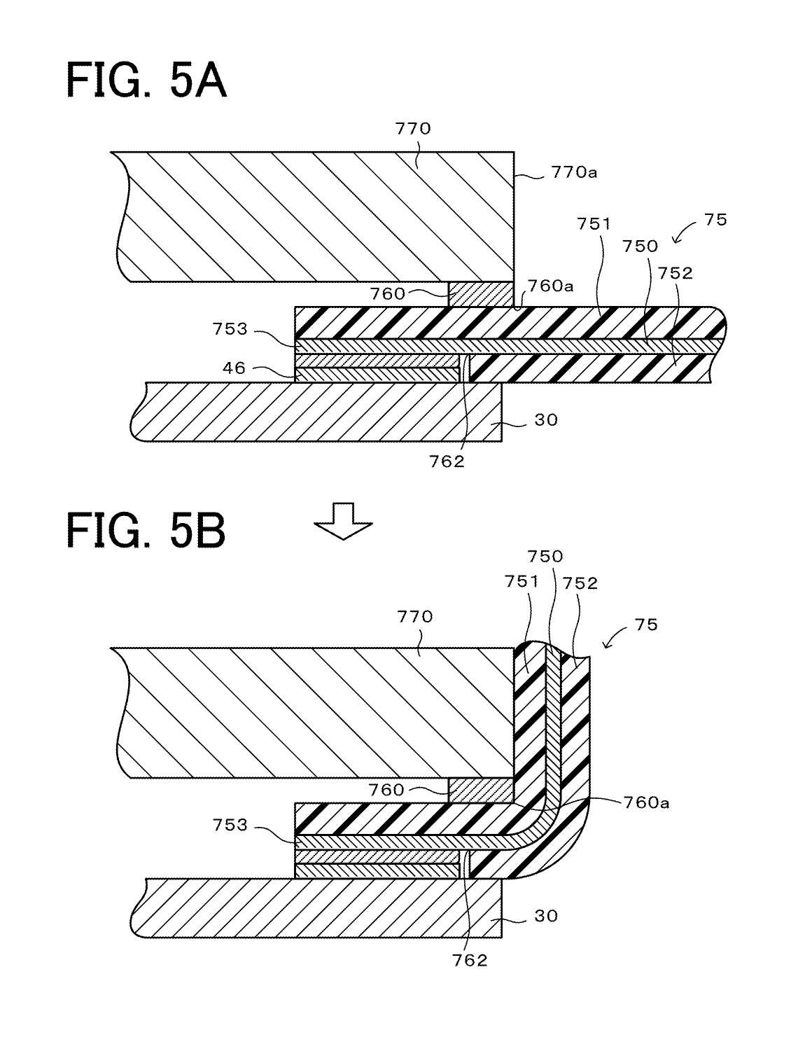

Next, a method for bending the connection FPC 75 bonded to the sheet heater 30 will be described below with reference to FIG. 5. FIG. 5 include explanatory views illustrating a procedure for bending the connection FPC 75. First, as illustrated in FIG. 5A, the bending-position guide 760 of the connection FPC 75 is held from above by a pressing plate 770. At this time, a side surface 770a of the pressing plate 770 is set so as not to protrude outward (to the right side in FIG. 5) from the edge 760a of the bending-position guide 760. To position the pressing plate 770 in this way, for example, a plurality of lift-pin insertion holes (not illustrated) penetrating the sheet heater 30 in the up-down direction may be utilized. That is, pins respectively insertable in a plurality of lift-pin insertion holes are formed on the pressing plate 770 beforehand, and design is made so that a bottom surface of the pressing plate 770 presses the bending-position guide 760 from above and the side surface 770a of the pressing plate 770 does not protrude outward from the edge 760a of the bending-position guide 760 in a state in which the pins are inserted in the lift-pin insertion holes. In FIG. 5A, the connection FPC 75 is bent by being turned on the edge 760a of the bending-position guide 760 in the counterclockwise direction. Then, as illustrated in FIG. 5B), the connection FPC 75 is bent along the edge 760a serving as the bending line. The edge 760a is disposed in the covering-layer projection area E where the covering layer 752 is projected on the support layer 751 (see FIG. 4). For this reason, the connection FPC 75 is bent at portions of the metal wires 750 covered with the covering layer 752, that is, at reinforced portions.

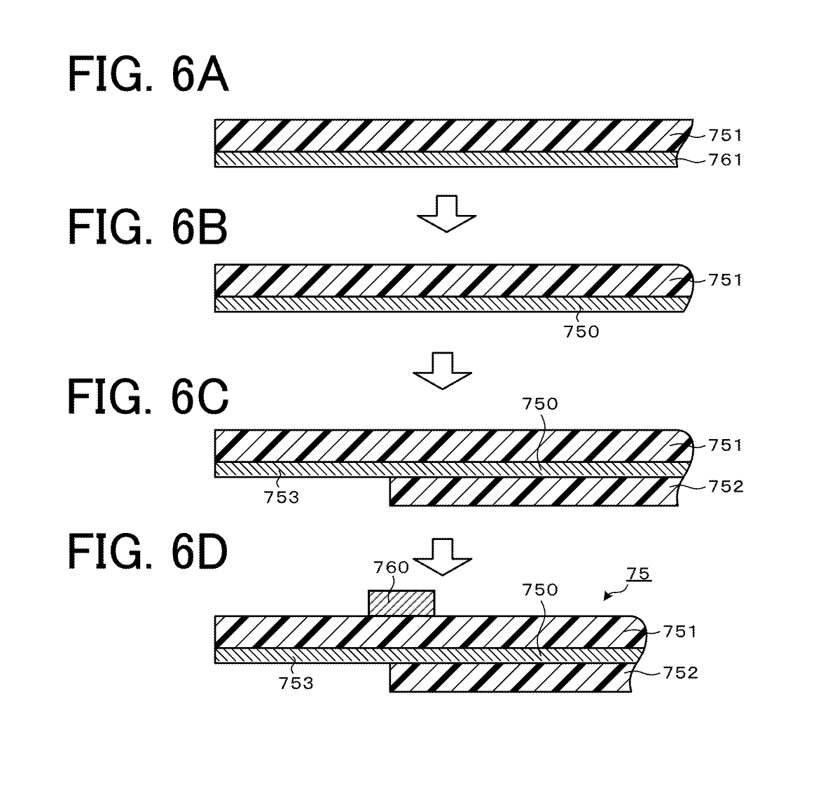

The connection FPC 75 is prepared through the following procedure. FIG. 6 include explanatory views illustrating a production process for the connection FPC 75. First, a one-sided copper-foiled support layer in which a copper foil 761 is stuck on one surface of a support layer 751 formed of resin is prepared (see FIG. 6B). Instead of the copper foil 761, other metal foils may be used. Next, metal wires 750 are formed in the copper foil 761 by patterning (see FIG. 6B). As the method for pattern formation, a wet etching method can be used. Next, the metal wires 750 are covered with a covering layer 752 formed of resin. As the method for covering with the covering layer 752, a lamination method can be used. However, contacts 753 serving as distal end portions of the metal wires 750 are not covered with the covering layer 752, but are exposed outside (see FIG. 6C). Next, a bending-position guide 760 is stuck on a predetermined position of the support layer 751 with adhesive (see FIG. 6D). As the bending-position guide 760, a rectangular heat-resistant resin plate (for example, a polyimide resin plate) can be used. Thus, a connection FPC 75 is obtained.

Next, a description will be given of a usage example of the plasma treatment apparatus 10 thus configurated. First, a wafer W is placed on the wafer mounting surface 22a of the electrostatic chuck 22. Then, the inside of the vacuum chamber 12 is adjusted to a predetermined vacuum degree by being depressurized by a vacuum pump. A coulomb force or a Johnson-Rahbeck force is generated by applying a direct-current voltage to the electrostatic electrode 24 of the electrostatic chuck 22, and the wafer W is thereby attracted and fixed to the wafer mounting surface 22a of the electrostatic chuck 22. Next, the inside of the vacuum chamber 12 is made into a process gas atmosphere with a predetermined pressure (for example, several tens of pascals to several hundreds of pascals). By applying a high-frequency voltage between the shower head 14 and the support pedestal 60 in this state, plasma is generated. The surface of the wafer W is etched by the generated plasma. Meanwhile, an unillustrated controller performs control so that the temperature of the wafer W reaches a predetermined target temperature. Specifically, the controller receives a detection signal from a temperature measuring sensor (not illustrated) for measuring the temperature of the wafer W, and controls the current to be supplied to the reference heater electrodes 44, the current to be supplied to the correction heater electrodes 34, and the temperature of the refrigerant to circulate in the refrigerant flow passage 62 so that the measured temperature of the wafer W coincides with the target temperature. In particular, the controller finely controls the current to be supplied to the correction heater electrodes 34 so that a temperature distribution does not occur in the wafer W. The temperature measuring sensor may be embedded in the resin sheet 32 or may be bonded to the surface of the resin sheet 32.

In the above-described embodiment, when the connection FPC 75 is bent, the edge 760a of the bending-position guide 760 serves as the bending line. The edge 760a is disposed in the covering-layer projection area E where the covering layer 752 is projected on the support layer 751. For this reason, the connection FPC 75 is bent at the portions of the metal wires 750 covered with the covering layer 752, that is, at the reinforced portions. Therefore, even when the connection FPC 75 is bent, the metal wires 750 are not easily broken.

The bending-position guide 760 is provided so as to cross the boundary 762 between the portions that are covered with the covering layer 752 and the portions that are not covered with the covering layer 752 in the metal wires 750. Although this boundary 762 tends to become the bending line when the connection FPC 75 is bent, since the bending-position guide 760 crosses the boundary 762, it prevents the boundary 762 from becoming the bending line.

Further, the distance L from the boundary 762 to the edge 760a of the bending-position guide 760 is set to be equal to or more than the thickness t of the portion of the connection FPC 75 in contact with the edge 760a. For this reason, when the connection FPC 75 is bent, the exposed portions of the metal wires 750 are not greatly affected.

It is needless to say that the present invention is not limited to the above-described embodiment and can be carried out in various embodiments as long as they belong to the technical scope of the invention.

While the support layer 751 is formed by a single layer in the above-described embodiment, it may be formed by stacking a plurality of layers. For example, as the support layer 751, a different resin layer may be stacked on one surface or each surface of the polyimide resin layer, a coverlay film may further be stacked on the different resin layer, or a single layer of a coverlay film may be used. This also applies to the covering layer 752.

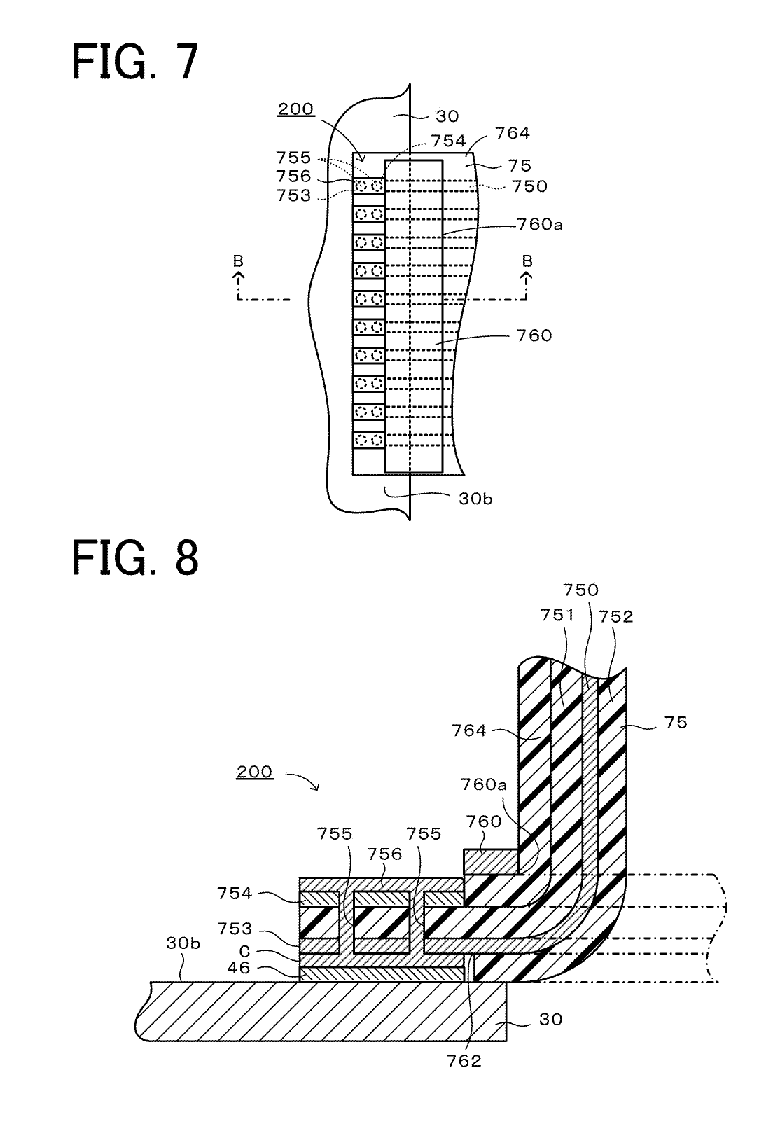

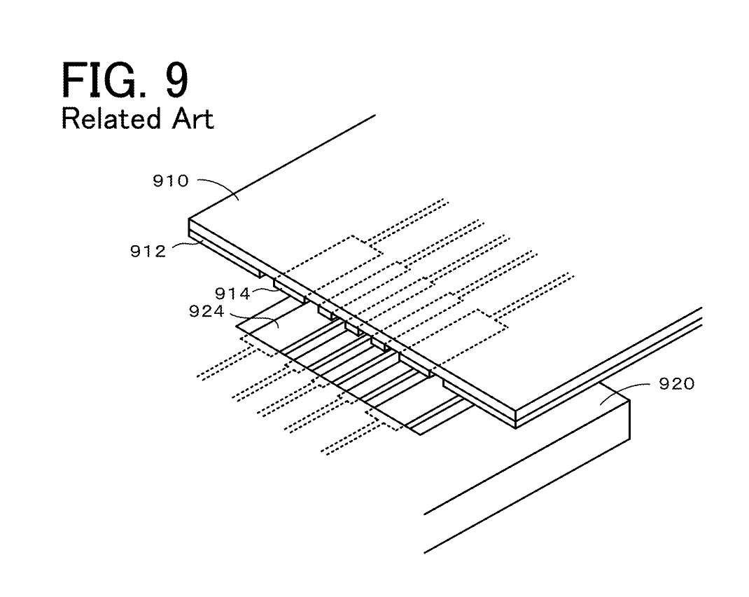

In the above-described embodiment, as illustrated in FIGS. 7 and 8, contact opposed lands 754 formed of metal and through holes 755 may be formed in the connection FPC 75. FIG. 7 is a plan view of a metal wiring bonding structure 200 when viewed from a lower surface 30b of a sheet heater 30, and FIG. 8 is a cross-sectional view taken along line B-B of FIG. 7. The contact opposed lands 754 are provided on a surface of a support layer 751 opposite from a surface on which metal wires 750 are provided, and are respectively opposed to a plurality of contacts 753. While a plurality of (for example, two) through holes 755 are provided here, only one through hole 755 may be provided. The transverse cross section (cross section taken along the horizontal plane) of the through holes 755 is circular, substantially circular, or elliptic. Inner walls of the through holes 755 may be covered with metal layers, for example, by plating. While a coverlay film 764 is stuck on an upper surface of the support layer 751, the contact opposed lands 754 are exposed from the coverlay film 764. A bending-position guide 760 is provided on an upper surface of the coverlay film 764. An edge 760a of the bending-position guide 760 is disposed in a covering-layer projection area where a covering layer 752 is projected on the coverlay film 764. A solder bonding member 756 covers surfaces of the contact opposed lands 754, and is filled inside the through holes 755 and in a bonding space C between the contacts 753 and heater lands 46. The solder bonding member 756 is obtained by melting wire solder by the contact opposed lands 754, supplying the melted solder to the bonding space C between the contacts 753 of the connection FPC 75 and the heater lands 46 of the sheet heater 30 through the through holes 755, and then hardening the melted solder. In this case, the melted solder is more easily supplied to the bonding space C than when the contact opposed lands 754 and the through holes 755 are not provided. As a result, it is possible to avoid the problem in that bonding is insufficient because the solder is not enough in the bonding space C. Also, when the contact opposed lands 754 are heated, heat thereof is transmitted to the bonding space C via the support layer 751, and heat of the melted solder is also transmitted to the bonding space C. For this reason, the bonding space C is entirely heated to high temperature. As a result, the melted solder supplied to the bonding space C easily and uniformly wets and spreads inside the bonding space C. In this way, the problem in that bonding is insufficient because the solder is not enough in the bonding space C is avoided, and the melted solder uniformly wets and spreads inside the bonding space C. Hence, the contacts 753 and the heater lands 46 are firmly bonded together. Further, similarly to the above-described embodiment, even when the connection FPC 75 is bent, the metal wires 750 are not easily broken. In this example, the support layer 751 and the coverlay film 764 correspond to the first resin layer of the present invention.

While the connection FPC 75 is given as an example of the flexible board in the above-described embodiment, the flexible board is not particularly limited thereto. For example, a flat cable may be used as the flexible board.

The present application claims priority from Japanese Patent Application No. 2016-128767 filed on Jun. 29, 2016, the entire contents of which are incorporated herein by reference.

What claimed is:

1. A flexible board including a plurality of metal wires between a first resin layer and a second resin layer, and an exposed region including contacts serving as end portions of the Metal wires and exposed from the second resin layer,
wherein a bending-position guide is provided on a surface of the first resin layer opposite from a surface on which the metal wires are provided, and
an edge of the bending-position guide serves as a bending line along which the flexible board is bent and is disposed in a projection area where the second resin layer is projected on the first resin layer.

2. The flexible board according to claim 1,
wherein the bending-position guide is provided so as to cross a boundary between portions of the metal wires that are covered with the second resin layer and portions of the metal wires that are not covered with the second resin layer.

3. The flexible board according to claim 1,
wherein a distance from the boundary between the portions of the metal wires that are covered with the second resin layer and the portions of the metal wires that are not covered with the second resin layer to the edge of the bending-position guide is set to be equal to or more than a thickness of a portion of the flexible board in contact with the edge.

4. The flexible board according to claim 1, including:
contact opposed lands formed of metal and respectively opposed to the contacts on the surface of the first resin layer opposite from the surface on which the metal wires are provided, and
through holes penetrating the contact opposed lands, the first resin layer, and the contacts.

5. A production method for a metal wiring bonding structure including the steps of;
(a) a step of brazing and soldering the contacts of the flexible board according to claim 1 to contacts of a different wiring board; and
(b) a step of bending the flexible board along a bending line formed by the edge of the bending-position guide.

6. The production method for a metal wiring bonding structure according to claim 5,
wherein in the step (b), the flexible board is bent along the bending line formed by the edge of the bending-position guide while the bending-position guide is held from above by a pressing member from a side of the flexible board close to the contacts.

7. The production method for a metal wiring bonding structure according to claim 5,
wherein in the step (a), the flexible board includes contact opposed lands formed of metal and respectively opposed to the contacts on the surface of the first resin layer opposite from the surface on which the metal wires are provided, and through holes penetrating the contact opposed lands, the first resin layer, and the contacts, the contacts of the flexible board are brazed and soldered by supplying a brazing and soldering material melted at the contact opposed lands of the flexible board between the contacts of the flexible board and the contacts of the different wiring board through the through holes and then hardening the brazing and soldering material.
